(19) United States
(12) Patent Application Publication
(10) Pub. No.: US 2026/0130026 A1
(43) Pub. Date: May 7, 2026

(54) DISPLAY DEVICE

(71) Applicant: AUO Corporation, Hsinchu City (TW)

(72) Inventors: Yung-Da Chen, Hsinchu City (TW); Yu-Sheng Huang, Hsinchu City (TW); Fu-Cheng Wei, Hsinchu City (TW); Hong-Shen Lin, Hsinchu City (TW)

(73) Assignee: AUO Corporation, Hsinchu City (TW)

(21) Appl. No.: 19/228,739

(22) Filed: Jun. 4, 2025

(30) Foreign Application Priority Data
Nov. 6, 2024 (TW) 113142605

(51) Int. Cl. H10H 29/34; H10H 29/39

(52) U.S. Cl. CPC H10H 29/34; H10H 29/39

(57) ABSTRACT

A display device includes a substrate, an insulating layer, first chip connection line structures, light emitting elements, a failed microchip, and a repair microchip. The insulating layer is located above of the substrate. The first chip connection line structures are located above the insulating layer and extend from a chip placement area to pixel areas around the chip placement area. The light emitting elements are respectively disposed in the pixel areas. The failed microchip is located in the chip placement area. The insulating layer laterally surrounds the failed microchip. The failed microchip is at least partially connected to the first chip connection line structures. The repair microchip is located in the chip placement area. The repair microchip is electrically connected to the light emitting elements through the first chip connection line structures.

### CROSS-REFERENCE TO RELATED APPLICATION

This application claims the priority benefit of Taiwan application serial no. 113142605, filed on Nov. 6, 2024. The entirety of the above-mentioned patent application is hereby incorporated by reference herein and made a part of this specification

### BACKGROUND

### Technical Field

The disclosure relates to a display device, and more particularly to a display device including a repair microchip.

### Description of Related Art

The micro light emitting diode (μLED) display panel is a display technology composed of tens of thousands of micro light emitting diodes. The micro light emitting diodes serve as light sources for pixels and have higher brightness, lower power consumption, and longer lifespan than traditional organic light emitting diode display panels or liquid crystal display panels.

In the micro light emitting diode display panel, the driving manner of the micro light emitting diodes is a key challenge because each micro light emitting diode requires precise signal control. Using microchip technology, microcontroller chips may be disposed in a display area of the display panel. The microchips directly provide signals to the micro light emitting diodes to drive and control the pixels. This technology greatly improves the precision and efficiency of signal transmission, while reducing the layout complexity of a driving circuit, which is conducive to the implementation of miniaturization and a high-resolution display panel.

### SUMMARY

The disclosure provides a display device, which may repair a failed microchip.

At least one embodiment of the disclosure provides a display device, which includes a substrate, an insulating layer, multiple first chip connection line structures, multiple light emitting elements, a failed microchip, and a repair microchip. The insulating layer is located above the substrate. The first chip connection line structures are located above the insulating layer and extend from the chip placement area to multiple pixel areas around the chip placement area. The light emitting elements are respectively disposed in the pixel areas. The failed microchip is located in the chip placement area. The insulating layer laterally surrounds the failed microchip. The failed microchip is at least partially connected to the first chip connection line structures. The repair microchip is located in the chip placement area. The repair microchip is electrically connected to the light emitting elements through the first chip connection line structures.

At least one embodiment of the disclosure provides a display device, which includes a substrate, an insulating layer, multiple first chip connection line structures, multiple light emitting elements, a first microchip, and a second microchip. The insulating layer is located above the substrate. The first chip connection line structures are located above the insulating layer and extend from the chip placement area to multiple pixel areas around the chip placement area. The light emitting elements are respectively disposed in the pixel areas. The first microchip is located in the chip placement area. The insulating layer laterally surrounds the first microchip. The first microchip is at least partially connected to the first chip connection line structures. The second microchip is located in the chip placement area. The second microchip is located above a top surface of the insulating layer. The first chip connection line structures are located between the first microchip and the second microchip. The second microchip is electrically connected to the light emitting elements through the first chip connection line structures.

### BRIEF DESCRIPTION OF THE DRAWINGS

FIG. 1A, FIG. 2A, FIG. 3A, and FIG. 4A are top schematic views of various stages of manufacturing a display device according to an embodiment of the disclosure.

FIG. 1B, FIG. 2B, FIG. 3B, and FIG. 4B are respectively cross-sectional schematic views taken along a line A-A′ and a line B-B′ of FIG. 1A, FIG. 2A, FIG. 3A, and FIG. 4A.

FIG. 5, FIG. 6, FIG. 7, FIG. 8, and FIG. 9A are top schematic views of various stages of manufacturing a display device according to another embodiment of the disclosure.

FIG. 9B is a cross-sectional schematic view taken along a line C-C′ of FIG. 9A.

FIG. 10 is a top schematic view of manufacturing a display device according to yet another embodiment of the disclosure.

FIG. 11 is a top schematic view of manufacturing a display device according to still another embodiment of the disclosure.

FIG. 12A, FIG. 12B, FIG. 12C, and FIG. 12D are respectively top schematic views of a second chip pad of a repair microchip according to some embodiments of the disclosure.

FIG. 13A is a top schematic view of a display device according to an embodiment of the disclosure.

FIG. 13B is a cross-sectional schematic view taken along a line A-A′ and a line C-C′ of FIG. 13A.

FIG. 13C is a top schematic view of a microchip of FIG. 13A.

### DESCRIPTION OF THE EMBODIMENTS

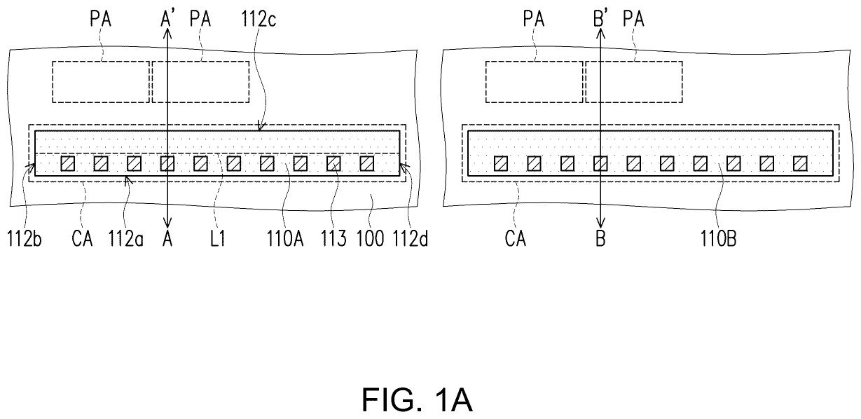

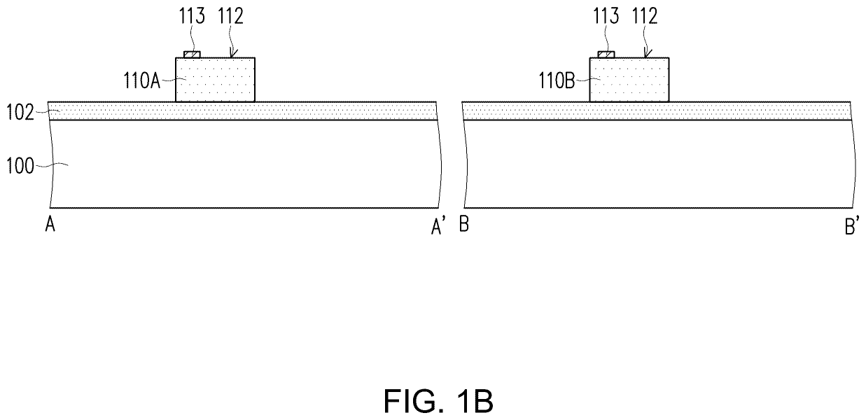

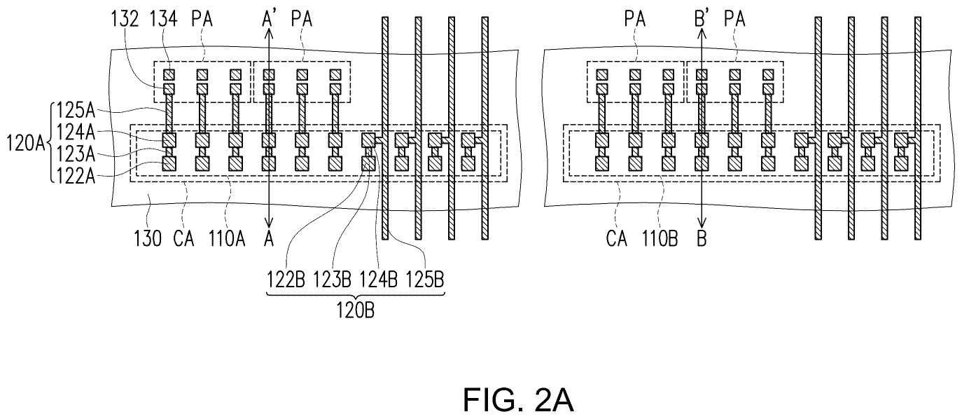

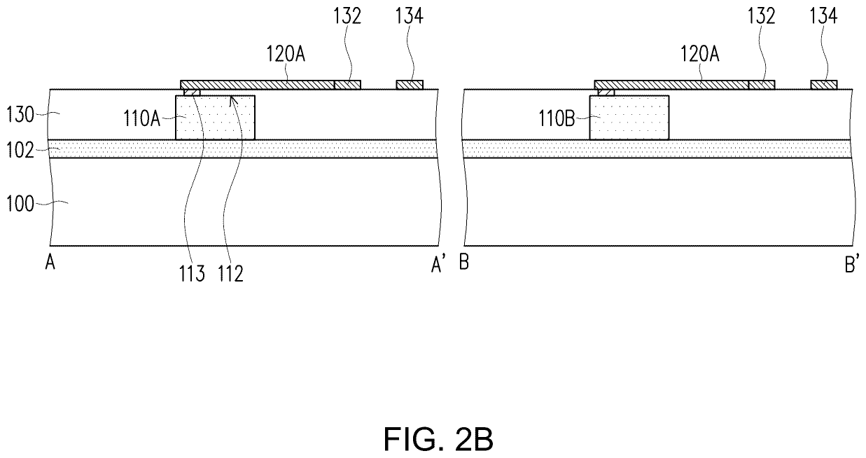

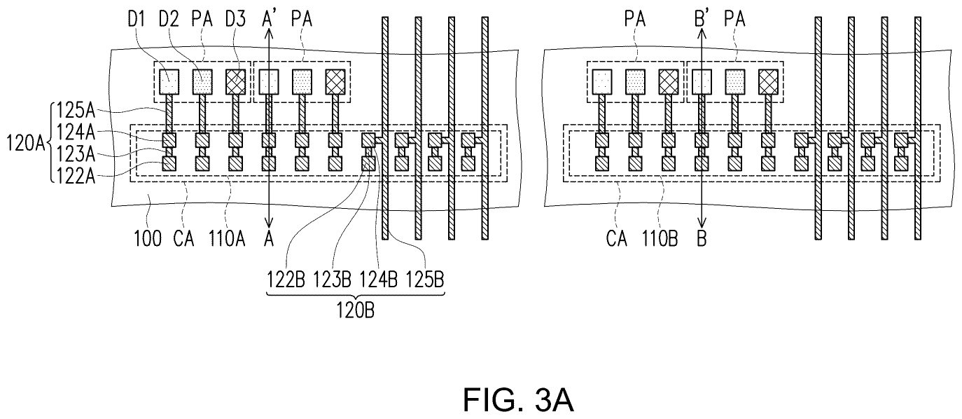

FIG. 1A, FIG. 2A, FIG. 3A, and FIG. 4A are top schematic views of various stages of manufacturing a display device 10A according to an embodiment of the disclosure. FIG. 1B, FIG. 2B, FIG. 3B, and FIG. 4B are respectively cross-sectional schematic views of FIG. 1A, FIG. 2A, FIG. 3A, and FIG. 4A, wherein FIG. 1B, FIG. 2B, FIG. 3B, and FIG. 4B respectively correspond to a line A-A′ and a line B-B′ of FIG. 1A, FIG. 2A, FIG. 3A, and FIG. 4A. Please refer to FIG. 1A and FIG. 1B. First microchips 110A and 110B are disposed on a substrate 100. For example, the first microchips 110A and 110B are attached to the substrate 100 through an adhesion layer 102.

In some embodiments, the substrate 100 is, for example, a rigid substrate, and the material thereof may be glass, quartz, organic polymer, an opaque/reflective material (for example, a conductive material, metal, wafer, ceramic, or other applicable materials), or other applicable materials. However, the disclosure is not limited thereto. In other embodiments, the substrate 100 may also be a flexible substrate or a stretchable substrate. For example, the materials of the flexible substrate and the stretchable substrate include polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (PU), or other suitable materials. In some embodiments, the substrate 100 is a transparent substrate and is suitable for a transparent display device.

The substrate 100 includes multiple chip placement areas CA and multiple pixel areas PA. The first microchips 110A and 110B are respectively disposed in different chip placement areas CA, and the pixel areas PA are respectively located around the corresponding chip placement areas CA. In some embodiments, the chip placement area CA and the pixel area PA are both disposed in a display area of the display device. Through disposing the chip placement area CA in the display area, the bezel size of the display device may be reduced. The pixel area PA is a region for disposing a light emitting element in a subsequent process.

In the embodiment, the first microchips 110A and 110B are attached to a top surface of the substrate 100 through the adhesion layer 102, but the disclosure is not limited thereto. In other embodiments, the top surface of the substrate 100 includes a circuit structure (not shown), and the first microchips 110A and 110B are attached to the circuit structure through the adhesion layer 102.

In the embodiment, the entire adhesion layer 102 is formed above the substrate 100, and a part of the adhesion layer 102 does not overlap with the first microchips 110A and 110B, but the disclosure is not limited thereto. In other embodiments, multiple adhesion layers 102 separated from each other respectively attach the first microchips 110A and 110B to the substrate 100. In some embodiments, the first microchip 110A, 110B includes a driving circuit.

In the embodiment, the first microchips 110A and 110B are both disposed in the chip placement areas CA with active surfaces 112 facing upward. The first microchips 110A and 110B each include multiple first chip pads 113. In some embodiments, the first chip pad 113 includes a metal bump structure. For example, the first chip pad 113 includes gold, copper, tin, silver, lead, indium, other metal materials, or a combination of the above materials. The first chip pad 113 is disposed on the active surface 112. In some embodiments, the active surface 112 includes two opposite first short sides 112b and 112d and two opposite first long sides 112a and 112c, wherein the center of each first chip pad 113 deviates from a connection line L1 of the midpoints of the two opposite first short sides 112b and 112d. The connection line L1 is a virtual line segment, not an actual line segment. In the embodiment, the midpoints of the first chip pads 113 are all located between the connection line L1 and the first long side 112a, but the disclosure is not limited thereto. In other embodiments, the midpoints of a part of the first chip pads 113 are located between the connection line L1 and the first long side 112a, and the midpoints of another part of the first chip pads 113 are located between the connection line L1 and the first long side 112c. In some embodiments, the first microchips 110A and 110B each include the first chip pads 113 arranged in a row. Compared to designing the first chip pads 113 into multiple rows, the probability of the first chip pads 113 in a single row contacting an erroneous routing due to offset is lower.

Please refer to FIG. 2A and FIG. 2B. An insulating layer 130 is formed above the substrate 100. The insulating layer 130 laterally surrounds the first microchips 110A and 110B. The first chip pads 113 of the first microchips 110A and 110B are exposed by the insulating layer 130.

Multiple first chip connection line structures 120A and multiple second chip connection line structures 120B are formed above the insulating layer 130. The first chip connection line structure 120A extends from the chip placement area CA to the pixel areas PA around the chip placement area CA, and the second chip connection line structure 120B extends from the chip placement area CA to a signal source area (not shown). In some embodiments, the signal source area is disposed in a bezel area of the display device, but the disclosure is not limited thereto.

In some embodiments, the first chip connection line structure 120A includes a first chip connection pad 122A, a first connection line 123A, a first repair pad 124A, and a signal output line 125A. The first chip connection pad 122A, the first connection line 123A, and the first repair pad 124A are disposed in the chip placement area CA. The first chip connection pad 122A is configured to be connected to a part of the first chip pad 113. In the embodiment, the first chip connection pad 122A of the first chip connection line structure 120A is directly formed on the first chip pads 113 and directly contacts at least part of the first chip pads 113. The first connection line 123A connects the first chip connection pad 122A and the first repair pad 124A. The signal output line 125A is connected to the first repair pad 124A and extends from the first repair pad 124A to the pixel area PA. In some embodiments, the signal output line 125A is connected to a first light emitting diode bonding pad 132 in the pixel area PA. In some embodiments, the pixel area PA further includes one or more second light emitting diode bonding pads 134. In some embodiments, the second light emitting diode bonding pads 134 are connected to each other and are electrically connected to a common voltage.

In some embodiments, the second chip connection line structure 120B includes a second chip connection pad 122B, a second connection line 123B, a second repair pad 124B, and a signal input line 125B. The second chip connection pad 122B, the second connection line 123B, and the second repair pad 124B are disposed in the chip placement area CA. The second chip connection pad 122B is configured to be connected to another part of the first chip pad 113. In the embodiment, the second chip connection pad 122B of the second chip connection line structure 120B is directly formed on the first chip pads 113 and directly contacts at least part of the first chip pads 113. The second connection line 123B connects the second chip connection pad 122B and the second repair pad 124B. The signal input line 125B is connected to the second repair pad 124B and extends from the second repair pad 124B to a signal source area (not shown). In some embodiments, a signal source provides a signal to the first microchip 110A, 110B through the second chip connection line structure 120B.

Please refer to FIG. 3A and FIG. 3B. Light emitting elements D1, D2, and D3 are respectively disposed in the pixel areas PA. The light emitting elements D1, D2, and D3 are located above the insulating layer 130, and the light emitting elements D1, D2, and D3 are each bonded to the first light emitting diode bonding pad 132 and the second light emitting diode bonding pad 134. In some embodiments, the light emitting elements D1, D2, and D3 include micro light emitting diodes. For example, the light emitting elements D1, D2, and D3 are respectively a red micro light emitting diode, a green micro light emitting diode, and a blue micro light emitting diode.

Before or after the light emitting elements D1, D2, and D3 are disposed in the pixel area PA, the first microchips 110A and 110B are tested to confirm whether the first microchips 110A and 110B may operate normally. In the embodiment, the first microchip 110A cannot operate normally, but the first microchip 110B may operate normally. For example, the first microchip 110A may be offset when placed on the substrate 100 or may have an internal defect, causing the first microchip 110A to be unable to output and/or receive expected signals. The first microchip 110A may also be referred to as a failed microchip. In the embodiment, the failed microchip (that is, the first microchip 110A) is located in the chip placement area CA. The insulating layer 130 laterally surrounds the failed microchip, and the failed microchip is at least partially connected to the first chip connection line structures 120A and the second chip connection line structures 120B. In some embodiments, because the failed microchip is offset when placed, a part of the first chip pads 113 of the failed microchip is not bonded to the first chip connection line structure 120A and the second chip connection line structure 120B.

Please refer to FIG. 4A and FIG. 4B. After confirming that the first microchip 110A is the failed microchip, a repair process is performed. Specifically, a repair microchip 210 is disposed in the chip placement area CA corresponding to the failed microchip. The chip placement area CA corresponding to the first microchip 110B that may operate normally does not need to be provided with the repair microchip 210. In some embodiments, the repair microchip 210 has the same structural design as the first microchips 110A and 110B, so there is no need to redesign the microchip for the repair process. For example, the relative positions between second chip pads 213 on the repair microchip 210 are equal to the relative positions between the first chip pads 113 of each of the first microchips 110A and 110B. In some embodiments, the second chip pad 213 includes a metal bump structure. For example, the second chip pad 213 includes gold, copper, tin, silver, lead, indium, other metal materials, or a combination of the above materials.

The repair microchip 210 is located above the insulating layer 130 and is bonded to the corresponding first chip connection line structure 120A and second chip connection line structure 120B through connection structures 215. Specifically, the second chip pads 213 of the repair microchip 210 are bonded to the first repair pad 124A of the corresponding first chip connection line structure 120A and the second repair pad 124B of the corresponding second chip connection line structure 120B through the connection structures 215. The connection structure 215 includes, for example, solder (for example, indium, tin, other suitable metal materials, or a combination of the above materials), conductive glue, or other conductive connection materials. The repair microchip 210 is electrically connected to the light emitting elements D1, D2, and D3 by the first chip connection line structure 120A corresponding to the failed microchip. At the same time, the repair microchip 210 is electrically connected to the signal source through the second chip connection line structure 120B corresponding to the failed microchip. For example, the first chip connection line structure 120A is configured to provide data signals from the microchip to the light emitting elements D1, D2, and D3, and the second chip connection line structure 120B is configured to provide input signals to the microchip.

In the embodiment, the repair microchip 210 is disposed in the chip placement area CA with an active surface 212 facing downward. The second chip pad 213 of the repair microchip 210 is disposed on the active surface 212. In some embodiments, the active surface 212 includes two opposite second short sides 212b and 212d and two opposite second long sides 212a and 212c, wherein the center of each second chip pad 213 deviates from a connection line L2 of the midpoints of the two opposite second short sides 212b and 212d. In the embodiment, the midpoints of the second chip pads 213 are all located between the connection line L2 and the second long side 212c, but the disclosure is not limited thereto. In other embodiments, the midpoints of a part of the second chip pads 213 are located between the connection line L2 and the second long side 212c, and the midpoints of another part of the second chip pads 213 are located between the connection line L2 and the second long side 212d. In some embodiments, the repair microchip 210 includes the second chip pads 213 arranged in a row. Compared to designing the second chip pads 213 into multiple rows, the probability of the second chip pads 213 in a single row contacting an erroneous routing due to offset is lower.

In some embodiments, the failed microchip (that is, the first microchip 110A) at least partially overlaps with the repair microchip 210 in a direction ND perpendicular to the top surface of the substrate 100. Therefore, the impact of the repair microchip 210 on the display area may be reduced. In some embodiments, when the display device 10A is a transparent display device, the transmittance of the display device 10A may be improved through overlapping the repair microchip 210 with the failed microchip. In some embodiments, the active surface 112 of the failed microchip (that is, the first microchip 110A) faces the active surface 212 of the repair microchip 210, but the first chip pad 113 does not overlap with the second chip pad 213 in the direction ND perpendicular to the top surface of the substrate 100.

In some embodiments, the second repair pad 124B is disposed between the second chip connection pad 122B and the signal input line 125B. Such a design allows the second connection line 123B between the second repair pad 124B and the second chip connection pad 122B to be cut off through a cutting process (for example, laser cutting or other suitable cutting manners) before installing the repair microchip 210, which may ensure that the first microchip 110A no longer receives input signals through the second chip connection line structure 120B, while the repair microchip 210 may still receive input signals from the signal source through the second repair pad 124B and the signal input line 125B. Similarly, the first repair pad 124A is located between the first chip connection pad 122A and the signal output line 125A. The first connection line 123A between the first repair pad 124A and the first chip connection pad 122A is cut off through a cutting process to ensure that the first microchip 110A no longer outputs signals to the light emitting elements D1, D2, and D3, while the repair microchip 210 may still output signals to the light emitting elements D1, D2, and D3 through the first repair pad 124A and the signal output line 125A.

In other embodiments, when the repair process does not require cutting the first connection line 123A and the second connection line 123B, the position of the first repair pad 124A and the position of the first chip connection pad 122A may be swapped, and the position of the second repair pad 124B and the position of the second chip connection pad 122B may also be swapped.

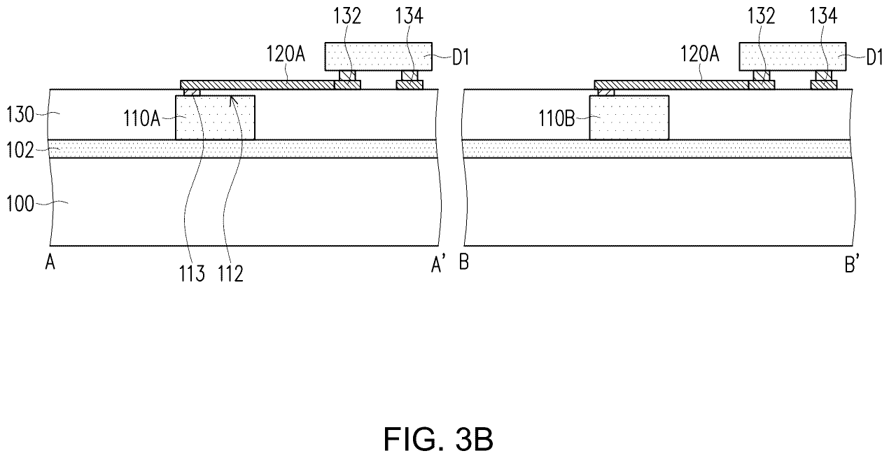

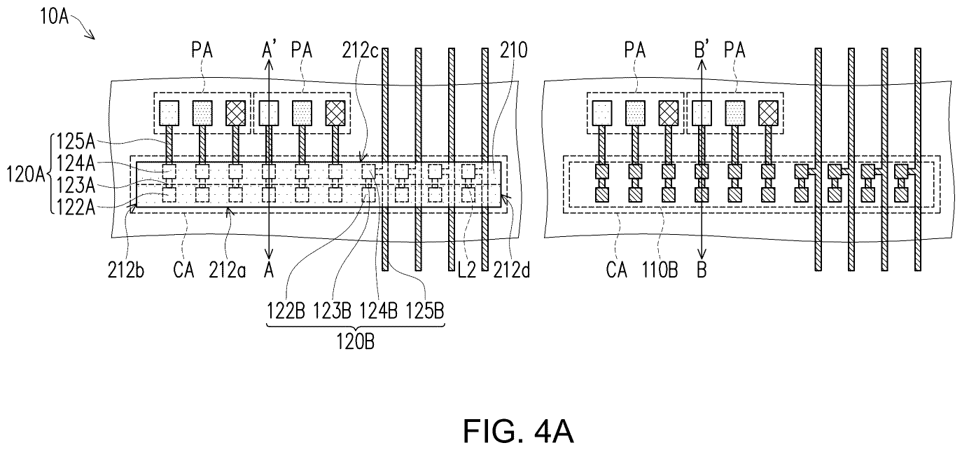

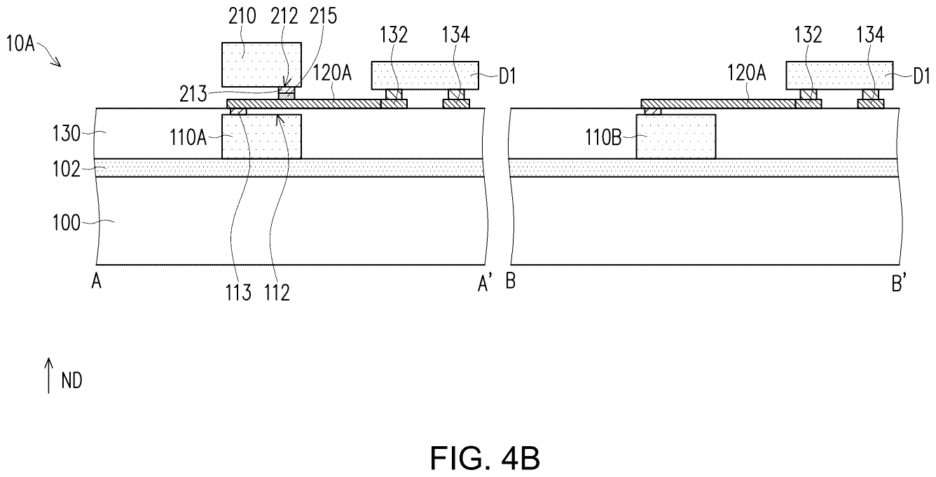

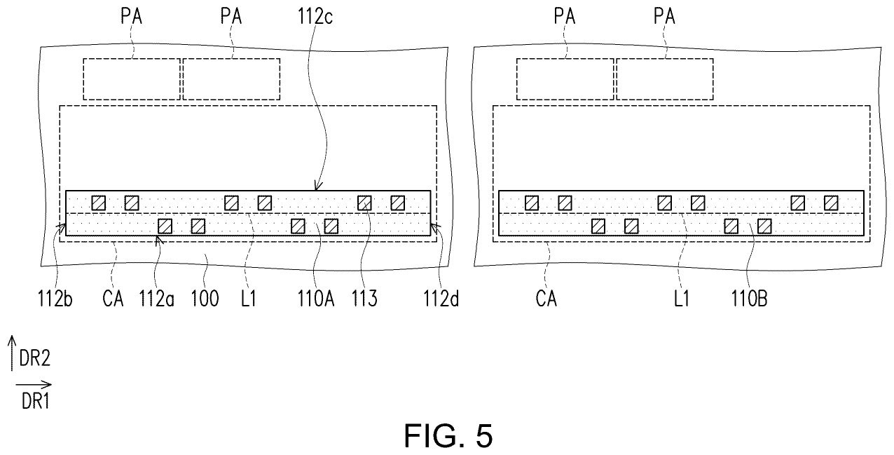

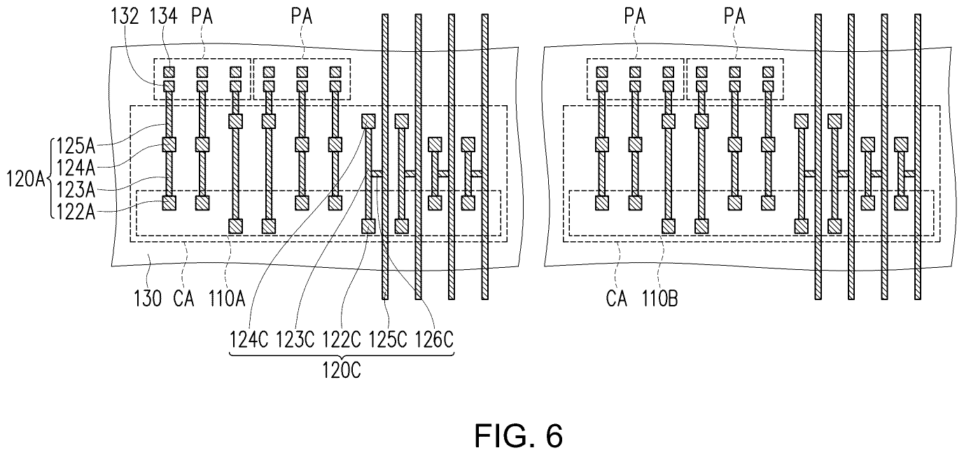

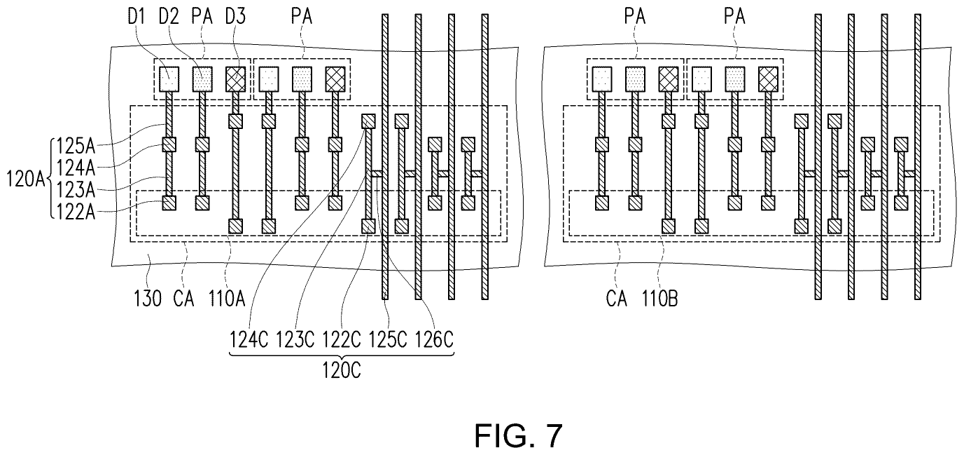

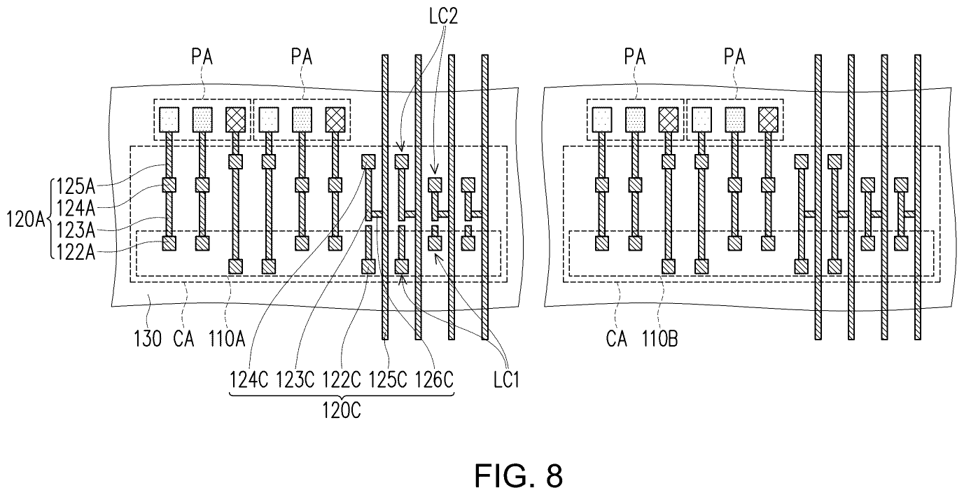

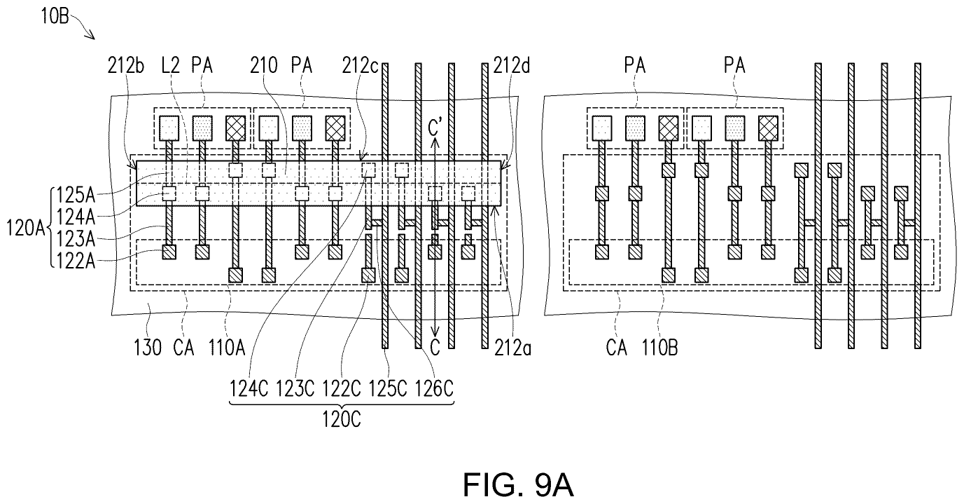

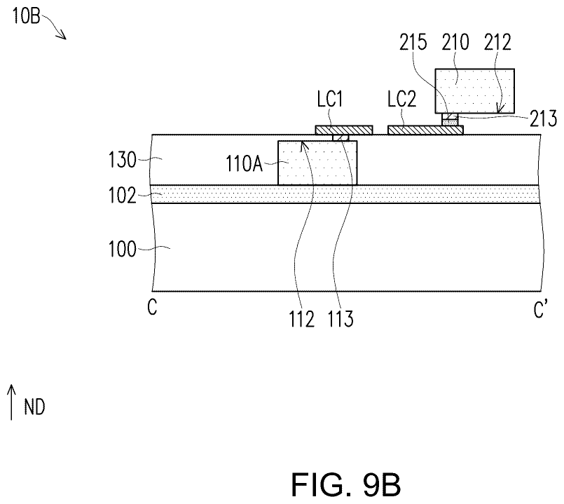

FIG. 5, FIG. 6, FIG. 7, FIG. 8, and FIG. 9A are top schematic views of various stages of manufacturing a display device 10B according to another embodiment of the disclosure. FIG. 9B is a cross-sectional schematic view taken along a line C-C′ of FIG. 9A. Please refer to FIG. 5. The first microchips 110A and 110B are both disposed in the chip placement area CA with the active surfaces 112 facing upward. In the embodiment, the first chip pads 113 of each of the first microchips 110A and 110B are displaced along a first direction DR1. Specifically, the midpoints of a part of the first chip pads 113 are located between the connection line L1 and the first long side 112a, and the midpoints of another part of the first chip pads 113 are located between the connection line L1 and the first long side 112c. In some embodiments, the first microchips 110A and 110B each include the first chip pads 113 arranged in a row along the first direction DR1. In the embodiment, being arranged in a row along the first direction DR1 means that the first chip pads 113 do not overlap with each other in a second direction DR2 perpendicular to the first direction DR1. Compared to designing the first chip pads 113 into multiple rows, the probability of the first chip pads 113 in a single row contacting an erroneous routing due to offset is lower.

Please refer to FIG. 5 and FIG. 6. The insulating layer 130 is formed above the substrate 100. The insulating layer 130 laterally surrounds the first microchips 110A and 110B. The first chip pads 113 of the first microchips 110A and 110B are exposed by the insulating layer 130.

The first chip connection line structures 120A and multiple second chip connection line structures 120C are formed above the insulating layer 130. The first chip connection line structure 120A extends from the chip placement area CA to the pixel areas PA around the chip placement area CA, and the second chip connection line structure 120C extends from the chip placement area CA to the signal source area (not shown). In some embodiments, the signal source area is disposed in the bezel area of the display device, but the disclosure is not limited thereto.

In some embodiments, the second chip connection line structure 120C includes a second chip connection pad 122C, a second connection line 123C, a second repair pad 124C, a signal input line 125C, and a bridging line 126C. The second chip connection pad 122C, the second connection line 123C, the second repair pad 124C, and the bridging line 126C are disposed in the chip placement area CA. The first chip connection pad 122A is configured to be connected to a part of the first chip pad 113, and the second chip connection pad 122C is configured to be connected to another part of the first chip pad 113. In the embodiment, the second chip connection pad 122C of the second chip connection line structure 120C is directly formed on the first chip pads 113 and directly contacts at least part of the first chip pads 113. The second connection line 123C connects the second chip connection pad 122C and the second repair pad 124C. The signal input line 125C is connected to the second connection line 123C through the bridging line 126C and extends to the signal source area (not shown). In some embodiments, the signal source provides signals to the first microchips 110A and 110B through the second chip connection line structures 120C.

Please refer to FIG. 6 and FIG. 7. The light emitting elements D1, D2, and D3 are respectively disposed in the pixel areas PA. The light emitting elements D1, D2, and D3 are located above the insulating layer 130 and are bonded to the first light emitting diode bonding pad 132 and the second light emitting diode bonding pad 134.

Before or after the light emitting elements D1, D2, and D3 are disposed in the pixel area PA, the first microchips 110A and 110B are tested to confirm whether the first microchips 110A and 110B may operate normally. In the embodiment, the first microchip 110A cannot operate normally, but the first microchip 110B may operate normally. For example, the first microchip 110A may be offset when placed on the substrate 100 or may have an internal defect, causing the first microchip 110A to be unable to output and/or receive expected signals. The first microchip 110A may also be referred to as the failed microchip.

Please refer to FIG. 8. After confirming that the first microchip 110A is the failed microchip, the second connection line 123C between the second repair pad 124C and the second chip connection pad 122C is cut off through a cutting process (for example, laser cutting or other suitable cutting manners). For example, at least one of the second chip connection line structures 120C is cut to have a signal disconnection portion LC1 (such as including the second chip connection pad 122C and a part of the second connection line 123C connected to the second chip connection pad 122C) and a signal connection portion LC2 (such as including the second repair pad 124C, a part of the second connection line 123C connected to the second repair pad 124C, the bridging line 126C, and the signal input line 125C) separated from each other. The failed microchip (that is, the first microchip 110A) is electrically connected to the signal disconnection portion LC1, and the repair microchip 210 is electrically connected to the signal connection portion LC2.

Please refer to FIG. 9A and FIG. 9B. The repair microchip 210 is disposed in the chip placement area CA corresponding to the failed microchip (that is, the first microchip 110A). The chip placement area CA corresponding to the first microchip 110B that may operate normally does not need to be provided with the repair microchip 210.

The repair microchip 210 is located above the insulating layer 130 and is bonded to the corresponding first chip connection line structure 120A and second chip connection line structure 120C through the connection structures 215. Specifically, the second chip pad 213 of the repair microchip 210 is bonded to the first repair pad 124A of the corresponding first chip connection line structure 120A and the second repair pad 124C of the second chip connection line structure 120C through the connection structures 215. The repair microchip 210 is electrically connected to the light emitting elements D1, D2, and D3 by the corresponding first chip connection line structure 120A. At the same time, the repair microchip 210 is electrically connected to the signal source through the corresponding second chip connection line structure 120C. For example, the first chip connection line structure 120A is configured to provide data signals from the repair microchip 210 to the light emitting elements D1, D2, and D3, and the second chip connection line structure 120C is configured to provide an input signal to the repair microchip 210. In addition, since the second connection line 123C is already cut off, it may be ensured that the first microchip 110A cannot receive input signals through the signal input line 125C.

In FIG. 9A and FIG. 9B, the failed microchip (that is, the first microchip 110A) does not overlap with the repair microchip 210 in the direction ND perpendicular to the top surface of the substrate 100, but the disclosure is not limited thereto. In other embodiments, the failed microchip at least partially overlaps with the repair microchip 210.

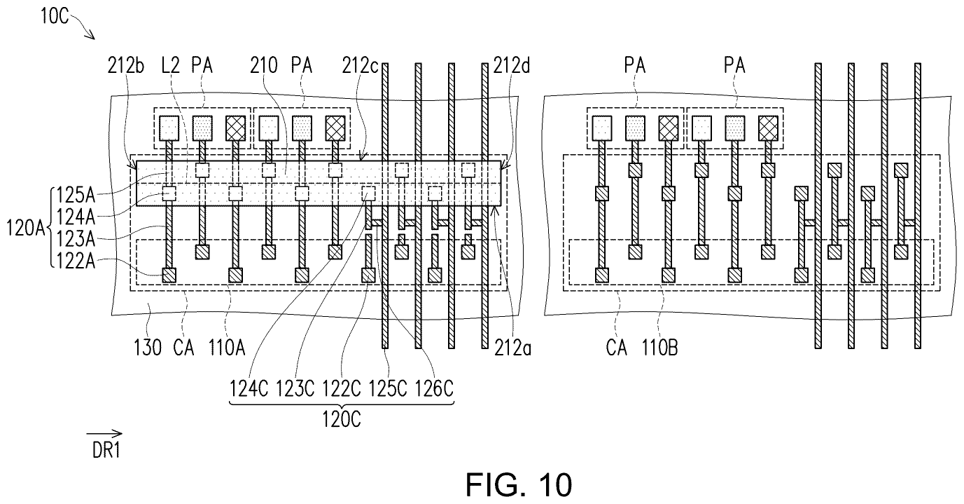

FIG. 10 is a top schematic view of manufacturing a display device 10C according to yet another embodiment of the disclosure. It must be noted here that the embodiment of FIG. 10 continues to use the reference numerals and some content of the embodiment of FIG. 5 to FIG. 9B, wherein the same or similar numerals are adopted to represent the same or similar elements, and the description of the same technical content is omitted. Reference may be made to the aforementioned embodiment for the description of the omitted part, which will not be repeated here.

The difference between the display device 10C of FIG. 10 and the display device 10B of FIG. 9A is that in the display device 10B, the first chip pads 113 are staggered in groups of two along the first direction DR1, and the second chip pads 213 are also arranged in the same manner, that is, staggered in groups of two along the first direction DR1. In contrast, in the display device 10C, the first chip pads 113 (the pads of the first microchips 110A and 110B bonded to the first chip connection pads 122A and the second chip connection pads 122C, not shown in FIG. 10) are staggered in units of one along the first direction DR1, and the second chip pads 213 (the pads of the repair microchip 210 bonded to the first repair pads 124A and the second repair pads 124C, not shown in FIG. 10) are also staggered in units of one along the first direction DR1.

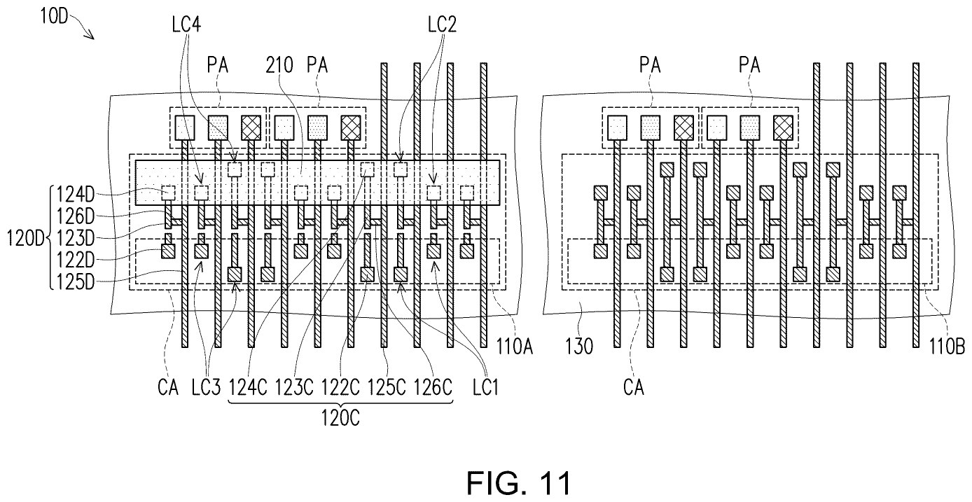

FIG. 11 is a top schematic view of manufacturing a display device 10D according to still another embodiment of the disclosure. It must be noted here that the embodiment of FIG. 11 continues to use the reference numerals and some content of the embodiment of FIG. 5 to FIG. 9B, wherein the same or similar numerals are adopted to represent the same or similar elements, and the description of the same technical content is omitted. Reference may be made to the aforementioned embodiment for the description of the omitted part, which will not be repeated here.

The difference between the display device 10D of FIG. 11 and the display device 10B of FIG. 9A is that in the display device 10D, the first chip connection line structure 120D includes a first chip connection pad 122D, a first connection line 123D, a first repair pad 124D, a signal output line 125D, and a bridging line 126D.

The first chip connection pad 122D, the first connection line 123D, the first repair pad 124D, and the bridging line 126D are disposed in the chip placement area CA. The first chip connection pad 122D is configured to be connected to a part of the first chip pads of the first microchip 110A, and the second chip connection pad 122C is configured to be connected to another part of the first chip pads of the first microchip 110A. In the embodiment, the first chip connection pad 122D of the first chip connection line structure 120D is directly formed on the first chip pads of the first microchip 110A and directly contacts at least part of the first chip pads of the first microchip 110A. The first connection line 123D connects the first chip connection pad 122D and the first repair pad 124D before a cutting process. The signal output line 125D is connected to the first connection line 123D through the bridging line 126D. The signal output line 125D extends to the pixel area PA. In some embodiments, the signal output line 125D is connected to the first light emitting diode bonding pad in the pixel area PA. In some embodiments, the pixel area PA further includes one or more second light emitting diode bonding pads. The light emitting elements D1, D2, and D3 are bonded to the first light emitting diode bonding pad and the second light emitting diode bonding pad.

In the embodiment, after confirming that the first microchip 110A is the failed microchip, in addition to cutting off the second connection line 123C between the second repair pad 124C and the second chip connection pad 122C through a cutting process, the first connection line 123D between the first repair pad 124D and the first chip connection pad 122D is also cut off through a cutting process to ensure that the first microchip 110A no longer outputs signals to the light emitting elements D1, D2, and D3.

For example, at least one of the first chip connection line structures 120D is cut to have a signal disconnection portion LC3 (such as including the second chip connection pad 122D and a part of the second connection line 123D connected to the second chip connection pad 122D) and a signal connection portion LC4 (such as including the second repair pad 124D, a part of the second connection line 123D connected to the second repair pad 124D, the bridging line 126D, and the signal input line 125D) separated from each other. Similarly, at least one of the second chip connection line structures 120C is cut to have the signal disconnection portion LC1 (such as including the second chip connection pad 122C and a part of the second connection line 123C connected to the second chip connection pad 122C) and the signal connection portion LC2 (such as including the second repair pad 124C, a part of the second connection line 123C connected to the second repair pad 124C, the bridging line 126C, and the signal input line 125C) separated from each other. The failed microchip (that is, the first microchip 110A) is electrically connected to the signal disconnection portion LC1 and the signal disconnection portion LC3, and the repair microchip 210 is electrically connected to the signal connection portion LC2 and the signal connection portion LC4.

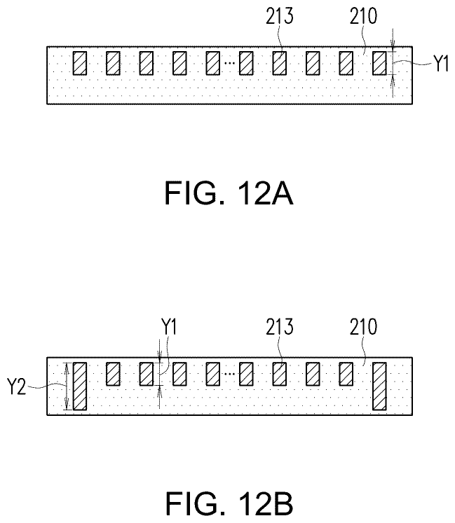

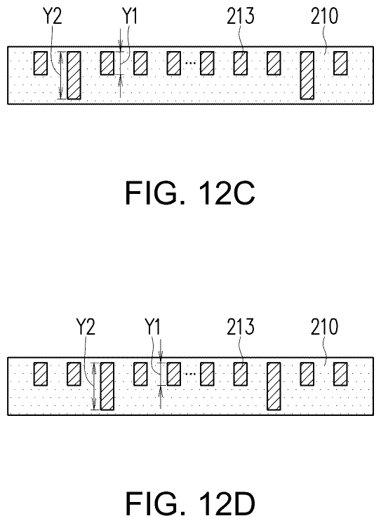

FIG. 12A, FIG. 12B, FIG. 12C, and FIG. 12D are respectively top schematic views of a second chip pad of a repair microchip according to some embodiments of the disclosure. Please refer to FIG. 12A. In some embodiments, the second chip pads 213 of the repair microchip 210 has a same length Y1, but the disclosure is not limited thereto. In other embodiments, the second chip pads 213 have two or more lengths, such as the length Y1 and a length Y2, as shown in FIG. 12B, FIG. 12C, and FIG. 12D, wherein the length Y2 is greater than the length Y1. The arrangement manner of the second chip pads 213 having the length Y1 and the second chip pads 213 having the length Y2 may be adjusted according to actual requirements. Through introducing the second chip pads 213 having different lengths, the issue that the repair microchip 210 is prone to tipping over when being pressed onto the chip connection line structure may be reduced.

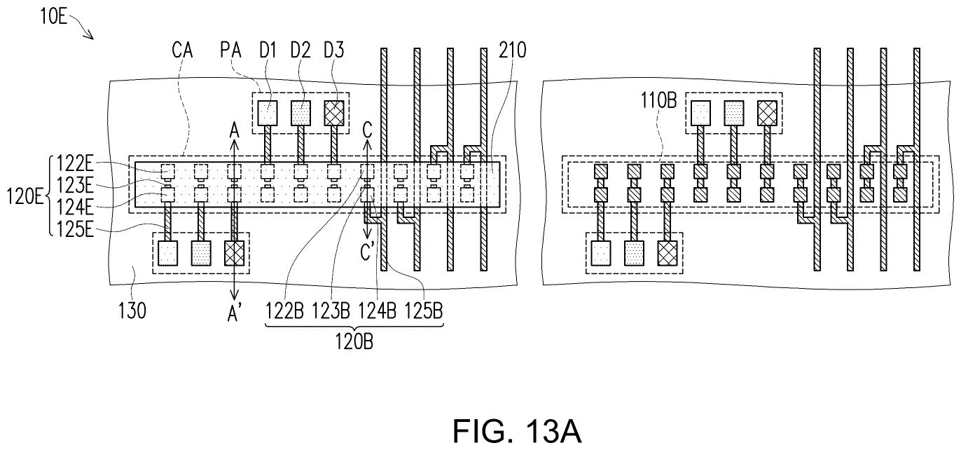

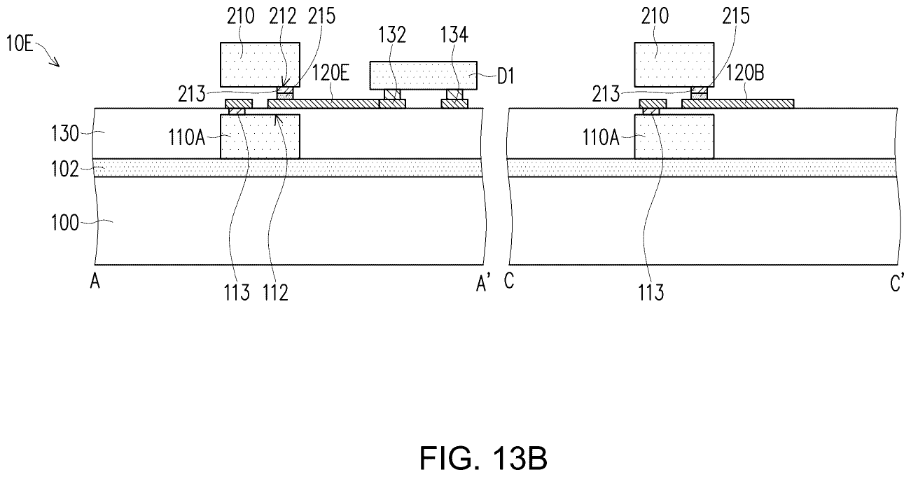

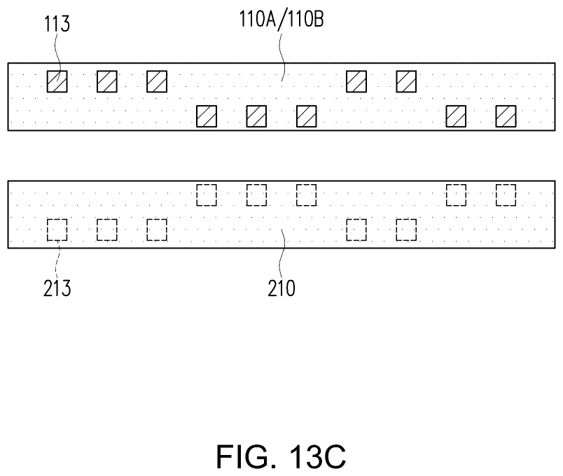

FIG. 13A is a top schematic view of a display device according to an embodiment of the disclosure. FIG. 13B is a cross-sectional schematic view taken along a line A-A′ and a line C-C′ of FIG. 13A. FIG. 13C is a top schematic view of a microchip of FIG. 13A, wherein the first microchips 110A and 110B have the same top view shape, so only a single microchip is illustrated in FIG. 13C. It must be noted here that the embodiment of FIG. 13A to FIG. 13C continues to use the reference numerals and some content of the aforementioned embodiments, wherein the same or similar numerals are adopted to represent the same or similar elements, and the description of the same technical content is omitted. Reference may be made to the aforementioned embodiments for the description of the omitted part, which will not be repeated here.

Please refer to FIG. 13A to FIG. 13C. A first chip connection line structure 120E and the second chip connection line structures 120B are formed above the insulating layer 130. The first chip connection line structure 120E extends from the chip placement area CA to the pixel areas PA around the chip placement area CA, and the second chip connection line structure 120B extends from the chip placement area CA to the signal source area (not shown). In FIG. 13A, a part of the pixel areas PA is located above the corresponding chip placement area CA, and another part of the pixel areas PA is located below the corresponding chip placement area CA.

In some embodiments, the first chip connection line structure 120E includes a first chip connection pad 122E, a first connection line 123E, a first repair pad 124E, and a signal output line 125E. The first chip connection pad 122E, the first connection line 123E, and the first repair pad 124E are disposed in the chip placement area CA. The first chip connection pad 122E is configured to be connected to a part of the first chip pads 113. In the embodiment, the first chip connection pad 122E of the first chip connection line structure 120E is directly formed on the first chip pads 113 and directly contacts at least part of the first chip pads 113. The first connection line 123E connects the first chip connection pad 122E and the first repair pad 124E. The signal output line 125E is connected to the first repair pad 124E. In some embodiments, the signal output line 125E is connected to the first light emitting diode bonding pad 132 in the pixel area PA and is electrically connected to the light emitting elements D1, D2, and D3 through the first light emitting diode bonding pad 132.

In the embodiment, in the same first chip connection line structure 120E, the first repair pad 124E is closer to the corresponding light emitting element D1, D2, D3 than the first chip connection pad 122E. Such a design allows the first connection line 123E between the first repair pad 124E and the first chip connection pad 122 to be cut off through a cutting process (for example, laser cutting or other suitable cutting manners) before installing the repair microchip 210. Even if the first connection line 123E is cut off, the repair microchip 210 on the first repair pad 124E may still be electrically connected to the light emitting elements D1, D2, and D3 through the first repair pad 124E and the signal output line 125E.

In some embodiments, the second chip connection line structure 120B includes the second chip connection pad 122B, the second connection line 123B, the second repair pad 124B, and the signal input line 125B. The second chip connection pad 122B, the second connection line 123B, and the second repair pad 124B are disposed in the chip placement area CA. The second chip connection pad 122B is configured to be connected to another part of the first chip pads 113. In the embodiment, the second chip connection pad 122B of the second chip connection line structure 120B is directly formed on the first chip pad 113 and directly contacts at least part of the first chip pads 113. The second connection line 123B connects the second chip connection pad 122B and the second repair pad 124B. The signal input line 125B is connected to the second repair pad 124B and extends from the second repair pad 124B to the signal source area (not shown). In some embodiments, the signal source provides signals to the first microchips 110A and 110B through the second chip connection line structure 120B.

In some embodiments, the second repair pad 124B is disposed between the second chip connection pad 122B and the signal input line 125B. Such a design allows the second connection line 123B between the second repair pad 124B and the second chip connection pad 122B to be cut off through a cutting process (for example, laser cutting or other suitable cutting manners) before installing the repair microchip 210, which may ensure that the first microchip 110A no longer receives input signals through the second chip connection line structure 120B, while the repair microchip 210 may still receive input signals from the signal source through the second repair pad 124B and the signal input line 125B.

In the embodiment, the repair microchip 210 has the same structural design as the first microchips 110A and 110B, so there is no need to redesign the microchip for the repair process. For example, the relative positions between the second chip pads 213 on the repair microchip 210 are equal to the relative positions between the first chip pads 113 of each of the first microchips 110A and 110B. In some embodiments, the second chip pad 213 includes a metal bump structure. For example, the second chip pad 213 includes gold, copper, tin, silver, lead, indium, other metal materials, or a combination of the above materials.

In summary, in the display device of the disclosure, the repair microchip may replace the failed microchip to output signals to the light emitting element, so as to improve the yield of the display device.

What is claimed is:

1. A display device, comprising:
a substrate;
an insulating layer, located above the substrate;
a plurality of first chip connection line structures, located above the insulating layer and extending from a chip placement area to a plurality of pixel areas around the chip placement area;
a plurality of light emitting elements, respectively disposed in the pixel areas;
a failed microchip, located in the chip placement area, wherein the insulating layer laterally surrounds the failed microchip, and the failed microchip is at least partially connected to the first chip connection line structures; and
a repair microchip, located in the chip placement area, wherein the repair microchip is electrically connected to the light emitting elements through the first chip connection line structures.

2. The display device according to claim 1, wherein the failed microchip at least partially overlaps with the repair microchip in a direction perpendicular to a top surface of the substrate.

3. The display device according to claim 1, wherein the repair microchip is located above the insulating layer.

4. The display device according to claim 1, wherein at least one of the first chip connection line structures is cut to have a first signal disconnection portion and a first signal connection portion separated from each other, wherein the failed microchip is electrically connected to the first signal disconnection portion, and the repair microchip is electrically connected to the first signal connection portion.

5. The display device according to claim 1, further comprising:
a plurality of second chip connection line structures, wherein at least one of the second chip connection line structures is cut to have a second signal disconnection portion and a second signal connection portion separated from each other, wherein the failed microchip is electrically connected to the second signal disconnection portion, and the repair microchip is electrically connected to the second signal connection portion, wherein the first chip connection line structures are configured to provide data signals from the repair microchip to the light emitting elements, and the second chip connection line structures are configured to provide an input signal to the repair microchip.

6. The display device according to claim 1, wherein an active surface of the failed microchip faces an active surface of the repair microchip.

7. The display device according to claim 1, wherein the failed microchip comprises a plurality of first chip pads, wherein the first chip pads are disposed on an active surface of the failed microchip, wherein the active surface of the failed microchip comprises two opposite first short sides and two opposite first long sides, wherein a center of each of the first chip pads deviates from a connection line of midpoints of the two opposite first short sides, wherein the repair microchip comprises a plurality of second chip pads, wherein the second chip pads are disposed on an active surface of the repair microchip, wherein the active surface of the repair microchip comprises two opposite second short sides and two opposite second long sides, wherein a center of each of the second chip pads deviates from a connection line of midpoints of the two opposite second short sides.

8. The display device according to claim 7, wherein the first chip pads do not overlap with the second chip pads in a direction perpendicular to a top surface of the substrate.

9. The display device according to claim 1, wherein the failed microchip comprises a plurality of first chip pads, wherein the first chip connection line structures directly contact at least part of the first chip pads, and the repair microchip is bonded to the first chip connection line structures through a plurality of connection structures.

10. The display device according to claim 9, wherein the connection structures comprise solder or conductive glue.

11. The display device according to claim 1, wherein the failed microchip comprises a plurality of first chip pads arranged in a row, and the repair microchip comprises a plurality of second chip pads arranged in a row.

12. The display device according to claim 1, wherein the repair microchip comprises a plurality of second chip pads, wherein the second chip pads have two or more lengths.

13. A display device, comprising:
a substrate;
an insulating layer, located above the substrate;
a plurality of first chip connection line structures, located above the insulating layer and extending from a chip placement area to a plurality of pixel areas around the chip placement area;
a plurality of light emitting elements, respectively disposed in the pixel areas;
a first microchip, located in the chip placement area, wherein the insulating layer laterally surrounds the first microchip, and the first microchip is at least partially connected to the first chip connection line structures; and
a second microchip, located in the chip placement area, wherein the second microchip is located above a top surface of the insulating layer, the first chip connection line structures are located between the first microchip and the second microchip, and the second microchip is electrically connected to the light emitting elements through the first chip connection line structures.

14. The display device according to claim 13, wherein the first microchip at least partially overlaps with the second microchip in a direction perpendicular to a top surface of the substrate.

15. The display device according to claim 13, wherein at least one of the first chip connection line structures is cut to have a first signal disconnection portion and a first signal connection portion separated from each other, wherein the first microchip is electrically connected to the first signal disconnection portion, and the second microchip is electrically connected to the first signal connection portion.

16. The display device according to claim 13, wherein an active surface of the first microchip faces an active surface of the second microchip.

17. The display device according to claim 13, wherein the first microchip comprises a plurality of first chip pads arranged in a row, and the second microchip comprises a plurality of second chip pads arranged in a row.

18. The display device according to claim 13, wherein the second microchip comprises a plurality of second chip pads, and the second chip pads have two or more lengths.
